(19) United States
(12) Patent Application Publication
(10) Pub. No.: US 2025/0149528 A1
(43) Pub. Date: May 8, 2025

(54) SEMICONDUCTOR DEVICE

(71) Applicant: Mitsubishi Electric Corporation, Tokyo (JP)

(72) Inventors: Kazuhiro NISHIMURA, Fukuoka (JP); Koichi TAGUCHI, Fukuoka (JP); Takeshi OMARU, Tokyo (JP); Korehide OKAMOTO, Fukuoka (JP); Yukimasa HIGASHI, Tokyo (JP)

(73) Assignee: Mitsubishi Electric Corporation, Tokyo (JP)

(21) Appl. No.: 18/838,369

(22) PCT Filed: Mar. 29, 2022
(86) PCT No.: PCT/JP2022/015495

§ 371 Date: Aug. 14, 2024

(51) Int. Cl. H01L 25/18; H01L 23/34; H01L 23/538; H03K 17/082

(52) U.S. Cl. CPC H01L 25/18; H01L 23/34; H01L 23/538; H03K 17/0822

(57) ABSTRACT

The present disclosure relates to a semiconductor device including: a first main terminal that is provided with a first potential; a second main terminal that is provided with a second potential lower than the first potential; a control terminal that is connected to an overcurrent detection circuit provided externally; at least one semiconductor element that includes a MOS transistor connected between the first main terminal and the second main terminal; and at least one diode that has a cathode electrically connected to the first main terminal and an anode electrically connected to the control terminal and protects the overcurrent detection circuit, wherein the at least one semiconductor element is mounted on a conductor plate, and the at least one semiconductor element and the at least one diode are sealed with an insulating resin.

### TECHNICAL FIELD

The present disclosure relates to semiconductor devices and, in particular, to a semiconductor device for use in a power converter, such as an inverter.

### BACKGROUND ART

A semiconductor device for use in a power converter and the like is provided with an overcurrent protection circuit that detects an overcurrent flowing through a switching element and stops driving of the switching element. A scheme of the overcurrent protection circuit has been dominated by two schemes: a desaturation voltage detection scheme and a sense current detection scheme, and one example of the former is a snubber apparatus in FIG. 5 disclosed in Patent Document 1.

### PRIOR ART DOCUMENTS

### Patent Document

Patent Document 1: Japanese Patent Application Laid-Open No. 2006-42410

### SUMMARY

### Problem to be Solved by the Invention

While a high breakdown voltage diode is used to protect a detection circuit in the desaturation voltage detection scheme, the high breakdown voltage diode is generally implemented on a control board and is thus electrically connected to a high voltage terminal, such as a drain terminal of the semiconductor device. It is thus necessary to secure a long insulating distance between the drain terminal of the semiconductor device connected to the high breakdown voltage diode on the control board and a terminal around the drain terminal, leading to a problem of reduction in design freedom of a substrate pattern of the control board and terminal arrangements of the semiconductor device. Furthermore, as disclosed in FIG. 8 of Patent Document 1, the high breakdown voltage diode and the switching element are implemented on the same conductive material and are filled with an insulating resin together with a printed board including a snubber circuit, resulting in a large heat capacity of the semiconductor device, poor thermal bonding between the high breakdown voltage diode and the switching element, and a problem of detection accuracy of an overcurrent detection circuit.

The present disclosure has been conceived to solve a problem as described above, and it is an object of the present disclosure to provide a semiconductor device having improved design freedom of a control board and the semiconductor device and improved detection accuracy of an overcurrent detection circuit.

### Means to Solve the Problem

A semiconductor device according to the present disclosure includes: a first main terminal that is provided with a first potential; a second main terminal that is provided with a second potential lower than the first potential; a control terminal that is connected to an overcurrent detection circuit provided externally; at least one semiconductor element that includes a MOS transistor connected between the first main terminal and the second main terminal; and at least one diode that has a cathode electrically connected to the first main terminal and an anode electrically connected to the control terminal and protects the overcurrent detection circuit, wherein the at least one semiconductor element is mounted on a conductor plate, and the at least one semiconductor element and the at least one diode are sealed with an insulating resin.

### Effects of the Invention

According to the semiconductor device according to the present disclosure, the at least one diode is provided within the semiconductor device, so that the first main terminal and the control terminal can be insulated by the insulating resin within the semiconductor device, design freedom of a control board provided externally and terminal arrangement of the semiconductor device is improved, and detection accuracy of the overcurrent detection circuit is improved.

### BRIEF DESCRIPTION OF DRAWINGS

FIG. 1 is a circuit diagram showing configurations of a semiconductor device according to Embodiment 1 according to the present disclosure and an overcurrent detection circuit.

FIG. 2 is a perspective view illustrating a configuration of the semiconductor device according to Embodiment 1 according to the present disclosure having been sealed with a resin.

FIG. 3 is a cross-sectional view of the semiconductor device according to Embodiment 1 according to the present disclosure.

FIG. 4 is a cross-sectional view of the semiconductor device according to Embodiment 1 according to the present disclosure.

FIG. 5 is a perspective view illustrating a configuration of a semiconductor device according to Embodiment 2 according to the present disclosure having been sealed with a resin.

FIG. 6 is a conceptual diagram illustrating a temperature distribution of a conductor plate when a semiconductor element of the semiconductor device according to Embodiment 2 according to the present disclosure is energized.

FIG. 7 is a perspective view illustrating a configuration of a semiconductor device according to Embodiment 3 according to the present disclosure having been sealed with a resin.

FIG. 8 is a conceptual diagram illustrating a temperature distribution of the conductor plate when semiconductor elements of the semiconductor device according to Embodiment 3 according to the present disclosure are energized.

FIG. 9 is a perspective view illustrating a configuration of a semiconductor device according to Embodiment 4 according to the present disclosure having been sealed with a resin.

FIG. 10 is a conceptual diagram illustrating a temperature distribution of the conductor plate when semiconductor elements of the semiconductor device according to Embodiment 4 according to the present disclosure are energized.

FIG. 11 is a perspective view illustrating a configuration of a semiconductor device according to Embodiment 5 according to the present disclosure having been sealed with a resin.

FIG. 12 is an equivalent circuit diagram of the semiconductor device according to Embodiment 5 according to the present disclosure.

FIG. 13 is a cross-sectional view of a semiconductor device according to Embodiment 6 according to the present disclosure.

FIG. 14 is a perspective view illustrating a configuration of a semiconductor device according to Embodiment 7 according to the present disclosure having been sealed with a resin.

FIG. 15 is a cross-sectional view of the semiconductor device according to Embodiment 7 according to the present disclosure.

FIG. 16 is a circuit diagram showing configurations of a semiconductor device according to Embodiment 8 according to the present disclosure and an overcurrent detection circuit.

FIG. 17 is a perspective view illustrating a configuration of the semiconductor device according to Embodiment 8 according to the present disclosure having been sealed with a resin.

FIG. 18 is a cross-sectional view of the semiconductor device according to Embodiment 8 according to the present disclosure.

FIG. 19 is a circuit diagram showing configurations of a semiconductor device according to Embodiment 9 according to the present disclosure and an overcurrent detection circuit.

FIG. 20 is a perspective view illustrating a configuration of the semiconductor device according to Embodiment 9 according to the present disclosure having been sealed with a resin.

FIG. 21 is a cross-sectional view of the semiconductor device according to Embodiment 9 according to the present disclosure.

FIG. 22 is a perspective view illustrating a configuration of a semiconductor device according to Embodiment 10 according to the present disclosure having been sealed with a resin.

FIG. 23 is an equivalent circuit diagram of the semiconductor device according to Embodiment 10 according to the present disclosure.

FIG. 24 is a cross-sectional view of the semiconductor device according to Embodiment 10 according to the present disclosure.

FIG. 25 is a circuit diagram showing configurations of a semiconductor device as underlying technology and an overcurrent detection circuit.

FIG. 26 is a diagram showing temperature characteristics of a saturation voltage of a MOSFET.

### DESCRIPTION OF EMBODIMENTS

### Embodiment 1

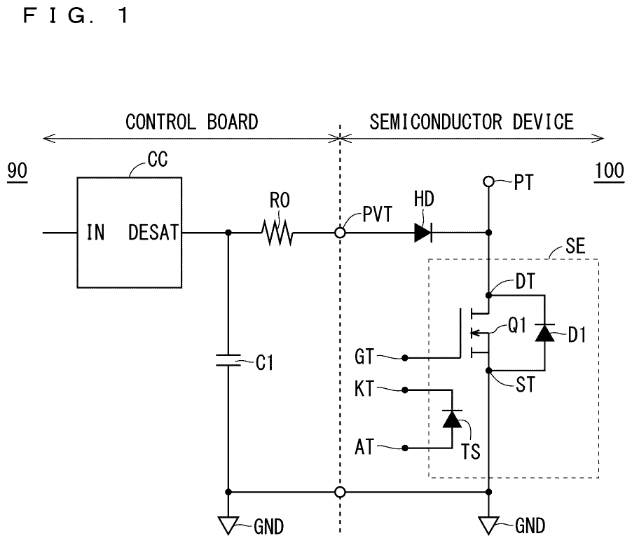

FIG. 1 is a circuit diagram showing configurations of a semiconductor device 100 according to Embodiment 1 according to the present disclosure and an overcurrent detection circuit 90. As shown in FIG. 1, the semiconductor device 100 includes a semiconductor element SE that includes a MOS transistor Q1 as a metal oxide semiconductor field effect transistor (MOSFET), a diode D1 connected in anti-parallel with the MOS transistor Q1, and a temperature sensor TS detecting a temperature of the MOS transistor Q1 that are connected between a power terminal PT that supplies power and a reference potential GND. The semiconductor device 100 also includes a high breakdown voltage diode HD that has a cathode connected to a drain terminal DT of the MOS transistor Q1 and has a breakdown voltage of several hundred volts to several kilovolts, for example. The high breakdown voltage diode HD is provided to protect the overcurrent detection circuit 90 against a high voltage applied to the power terminal PT.

A source terminal ST of the MOS transistor Q1 is connected to the reference potential GND and to an anode of the diode D1, and a cathode of the diode D1 is connected to the drain terminal DT.

The temperature sensor TS includes a temperature detection diode and has a cathode terminal KT and an anode terminal AT.

While a gate terminal GT of the MOS transistor Q1 and the cathode terminal KT and the anode terminal AT of the temperature sensor TS are connected to a control circuit CC provided to the overcurrent detection circuit 90, connections to the control circuit CC are omitted for the sake of simplicity.

While the control circuit CC provided to the overcurrent detection circuit 90 controls a gate signal of the MOS transistor Q1, monitors an output signal of the temperature sensor TS, and monitors an overcurrent determination threshold, only a detection terminal DESAT that detects the overcurrent determination threshold and a signal input terminal IN to which an external signal is input are shown in FIG. 1 for the sake of simplicity.

An anode of the high breakdown voltage diode HD is connected to a resistor R0 in the overcurrent detection circuit 90 via a control terminal PVT of the semiconductor device 100, and the resistor R0 is connected to the detection terminal DESAT of the control circuit CC. The resistor R0 is connected to one of electrodes of a capacitor C1, and the other one of the electrodes of the capacitor C1 is connected to a reference potential GND in the overcurrent detection circuit 90.

The reference potential GND in the overcurrent detection circuit 90 and the reference potential GND in the semiconductor device 100 are commonly connected.

While the semiconductor device 100 shown in FIG. 1 includes the semiconductor element that includes the MOS transistor Q1 and the diode D1 connected between the power terminal PT and the reference potential GND, the semiconductor device 100 can have a configuration of an inverter circuit in which a pair of a transistor and a diode similar to the MOS transistor Q1 and the diode D1 is connected between the reference potential GND and a ground potential and can have a configuration in which a plurality of inverter circuits are connected in parallel.

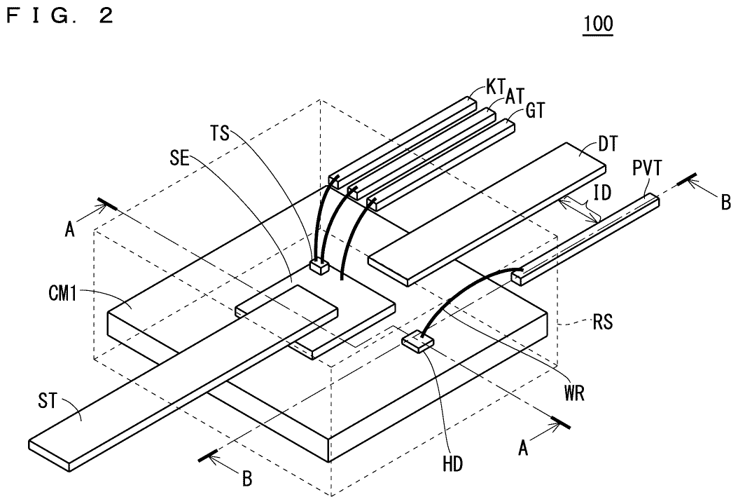

FIG. 2 is a perspective view illustrating a configuration of the semiconductor device 100 having been sealed with an insulating resin RS, and a contour of the insulating resin RS is indicated by dashed lines.

As illustrated in FIG. 2, the semiconductor device 100 includes a conductor plate CM1 that functions as a heat spreader as a substrate, and the semiconductor element SE is mounted on one main surface as an upper surface of the conductor plate CM1. A high thermal conductive material, such as copper and aluminum, is used for the conductor plate CM1, and the conductor plate CM1 functions as a buffer material between the semiconductor element SE and an external heat sink while increasing a heat dissipation efficiency.

The semiconductor element SE is an element in which the MOS transistor Q1 and the diode D1 shown in FIG. 1 are integrated, one end of the source terminal ST as a plate-like conductive material is connected to an upper surface as one main surface of the semiconductor element SE, and the other end of the source terminal ST externally protrudes from one of side surfaces of the insulating resin RS.

A lower surface as the other main surface of the semiconductor element SE is electrically connected to the conductor plate CM1. One end of the drain terminal DT as a plate-like conductive material is connected to the upper surface of the conductor plate CM1, and the other end of the drain terminal DT externally protrudes from one of the side surfaces of the insulating resin RS. The side surface of the insulating resin RS from which the other end of the source terminal ST protrudes and the side surface of the insulating resin RS from which the other end of the drain terminal DT protrudes are in an opposing relationship.

The temperature sensor TS is mounted on the upper surface of the semiconductor element SE, and a cathode electrode and an anode electrode, which are not illustrated, provided on an upper surface of the temperature sensor TS are respectively electrically connected to one end of the cathode terminal KT and one end of the anode terminal AT as plate-like conductive materials via wires WR. The other end of the cathode terminal KT and the other end of the anode terminal AT externally protrude from the same side surface of the insulating resin RS from which the other end of the drain terminal DT protrudes.

An output of the temperature sensor TS is fed back to the control circuit CC of the overcurrent detection circuit 90 via the cathode terminal KT and the anode terminal AT, and, when a temperature of the semiconductor element SE is higher than a predetermined value, protective operation, such as a stop of switching operation of the MOS transistor Q1, is performed. By mounting the temperature sensor TS on the upper surface of the semiconductor element SE, an accurate temperature of the semiconductor element SE can be acquired, and the protective operation can accurately be performed.

An unillustrated gate pad on the upper surface of the semiconductor element SE is electrically connected to one end of the gate terminal GT as a plate-like conductive material via a wire WR. The other end of the gate terminal GT externally protrudes from the same side surface of the insulating resin RS from which the other end of the drain terminal DT protrudes.

The high breakdown voltage diode HD is mounted on the upper surface of the conductor plate CM1 at a position away from the semiconductor element SE. The high breakdown voltage diode HD is electrically connected to one end of the control terminal PVT as a plate-like conductive material via a wire WR. The other end of the control terminal PVT externally protrudes from the same side surface of the insulating resin RS from which the other end of the drain terminal DT protrudes. An upper surface and a lower surface of the high breakdown voltage diode HD respectively serve as an anode and a cathode.

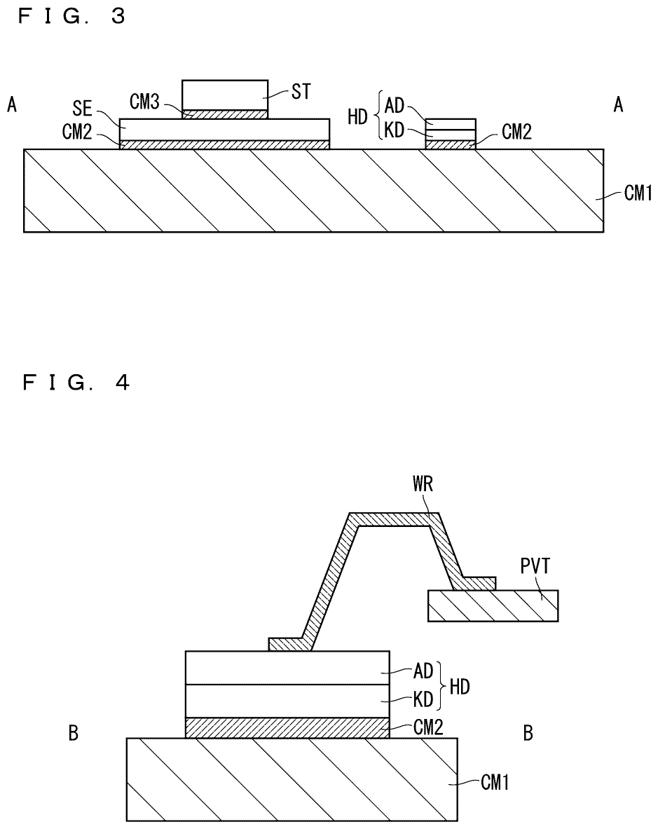

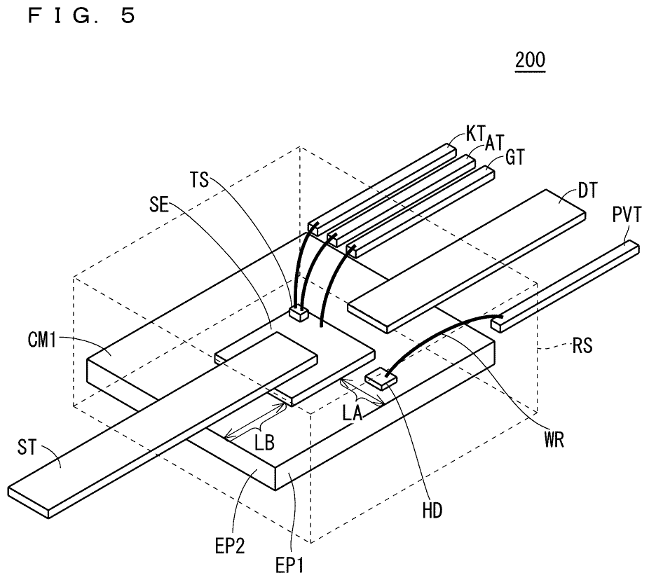

FIG. 3 is a cross-sectional view taken along the line A-A of FIG. 2, and FIG. 4 is a cross-sectional view taken along the line B-B of FIG. 2. The insulating resin RS is not illustrated in each of FIGS. 3 and 4.

As illustrated in FIG. 3, the semiconductor element SE and a cathode layer KD of the high breakdown voltage diode HD are connected to the upper surface of the conductor plate CM1 by conductive materials CM2. As the conductive materials CM2, solder, conductive resins, Ag sintered materials, and Cu sintered materials can be used, for example.

The source terminal ST is connected to an unillustrated source electrode of the MOS transistor Q1 on the upper surface of the semiconductor element SE by a conductive material CM3. The same material as the conductive materials CM2 can be used as the conductive material CM3.

A cathode electrode of the diode D1 of the semiconductor element SE is common to the source electrode of the MOS transistor Q1, and an anode electrode of the diode D1 is common to a drain electrode of the MOS transistor Q1.

As illustrated in FIG. 4, the cathode layer KD of the high breakdown voltage diode HD is in a lower surface side of the high breakdown voltage diode HD and is connected to the upper surface of the conductor plate CM1 by a conductive material CM2. An anode layer AD of the high breakdown voltage diode HD is in an upper surface side opposite the cathode layer KD, and the wire WR is connected to the anode layer AD by wire bonding. While a cathode electrode and an anode electrode can respectively be provided to the cathode layer KD and the anode layer AD, they are not illustrated for the sake of simplicity. The wire WR is connected to the one end of the control terminal PVT by wire bonding. An aluminum wire can be used as the wire WR, for example.

As described above, the semiconductor device 100 according to Embodiment 1 incorporates therein the high breakdown voltage diode HD to enable insulation of the terminals within the insulating resin RS, so that an insulating distance between the control terminal PVT and the drain terminal DT can be reduced compared with that in a conventional semiconductor device, and design freedom of the control board and terminal arrangement of the semiconductor device is improved. The insulating distance between the control terminal PVT and the drain terminal DT is defined by spacing ID indicated by an arrow in FIG. 2.

A desaturation detection voltage is defined by the sum of a saturation voltage of the MOS transistor Q1 as the switching element, a forward voltage of the high breakdown voltage diode HD, and a resistor power loss, and, when the switching element is the MOSFET, the saturation voltage of the MOSFET has large positive temperature characteristics to affect an operation temperature range of the overcurrent detection circuit.

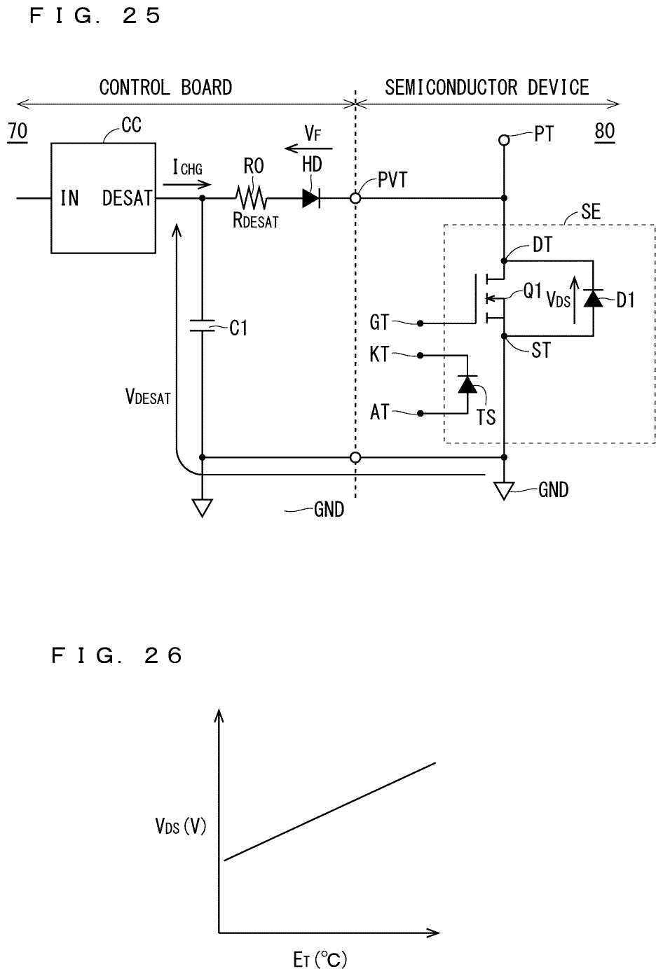

This problem will be described using an overcurrent detection circuit 70 as underlying technology shown in FIG. 25. In FIG. 25, the same components as those of the overcurrent detection circuit 90 and the semiconductor device 100 having been described with reference to FIG. 1 bear the same reference signs as those of the same components, and redundant description will be omitted.

As shown in FIG. 25, the overcurrent detection circuit 70 incorporates therein the high breakdown voltage diode HD, and the drain terminal DT of the MOS transistor Q1 of a semiconductor device 80 is connected to the control terminal PVT and the power terminal PT.

A cathode of the high breakdown voltage diode HD is connected to the control terminal PVT, and an anode of the high breakdown voltage diode HD is connected to the resistor R0 in the overcurrent detection circuit 70.

An overcurrent determination threshold V_{DESAT} of the overcurrent detection circuit 70 having such a configuration is determined by the sum of a saturation voltage V_{DS} of the transistor, a forward voltage V_{F} of the high breakdown voltage diode HD, the saturation voltage V_{DS} of the MOS transistor Q1, and the resistor power loss (I_{CHG}×R_{DESAT}) shown in FIG. 25 and is represented by an equation V_{DESAT}=(I_{CHG}×R_{DESAT})+V_{F}+V_{DS}. Herein, I_{CHG} is a current flowing through the resistor R1, and R_{DESAT} is a resistance value of the resistor R0.

FIG. 26 is a diagram showing temperature characteristics of the saturation voltage of the MOSFET, and a horizontal axis represents an environmental temperature E_{T} (° C.) and a vertical axis represents the saturation voltage V_{DS} (V).

As shown in FIG. 26, the saturation voltage V_{DS} of the MOSFET has a positive temperature characteristic trend toward a greater absolute value as the temperature increases, so that the overcurrent determination threshold V_{DESAT} increases with increasing environmental temperature E_{T}.

The control circuit CC monitors the overcurrent determination threshold, and, when the overcurrent determination threshold is equal to or greater than a given voltage, operation transitions to overcurrent protective operation, but, due to a limited monitoring range of the control circuit CC, an operating temperature range of an overcurrent protection circuit is affected when the overcurrent determination threshold is excessively high due to a high temperature.

In the semiconductor device 100, however, the high breakdown voltage diode HD is disposed adjacent to the MOS transistor Q1, which is a heat source, so that, compared with a case where the high breakdown voltage diode HD is provided external to the semiconductor device, a temperature of the high breakdown voltage diode HD increases, and the forward voltage decreases to act to counteract the temperature characteristics of the saturation voltage V_{DS} of the MOSFET to thereby improve detection accuracy of the overcurrent detection circuit 90.

### Embodiment 2

FIG. 5 is a perspective view illustrating a configuration of a semiconductor device 200 according to Embodiment 2. In FIG. 5, the same components as those of the semiconductor device 100 having been described with reference to FIG. 2 bear the same reference signs as those of the same components, and redundant description will be omitted.

The semiconductor device 200 illustrated in FIG. 5 has a configuration in which a distance LA from the semiconductor element SE to one end surface of the conductor plate CM1 and a distance LB from the semiconductor element SE to another end surface of the conductor plate CM1 are not the same.

Herein, the one end surface of the conductor plate CM1 is an end surface EP1 (a first end surface) parallel to a longitudinal direction of the source terminal ST and the drain terminal DT, and the other end surface is an end surface EP2 (a second end surface) orthogonal to the end surface EP1. In an example illustrated in FIG. 5, a case where the conductor plate CM1 is rectangular in plan view, and the semiconductor element SE being square in plan view is mounted at the center of the upper surface of the conductor plate CM1 is shown, and the distance LA (a first distance) to the end surface EP1 on a side of a long side of the conductor plate CM1 is shorter than the distance LB (a second distance) to the end surface EP2 on a side of a short side of the conductor plate CM1 to satisfy an inequality LA<LB. The high breakdown voltage diode HD is mounted on the conductor plate CM1 on a side of the end surface EP1 at a shorter distance from the semiconductor element SE.

Upon energization of the semiconductor element SE, a temperature of the conductor plate CM1 increases with the semiconductor element SE as a heat source, but, when the distance LA and the distance LB from the semiconductor element SE to the end surfaces of the conductor plate CM1 are not equal, thermal spread, that is, a temperature distribution is non-uniform, and a portion having a shorter distance has a temperature closer to the temperature of the semiconductor element SE.

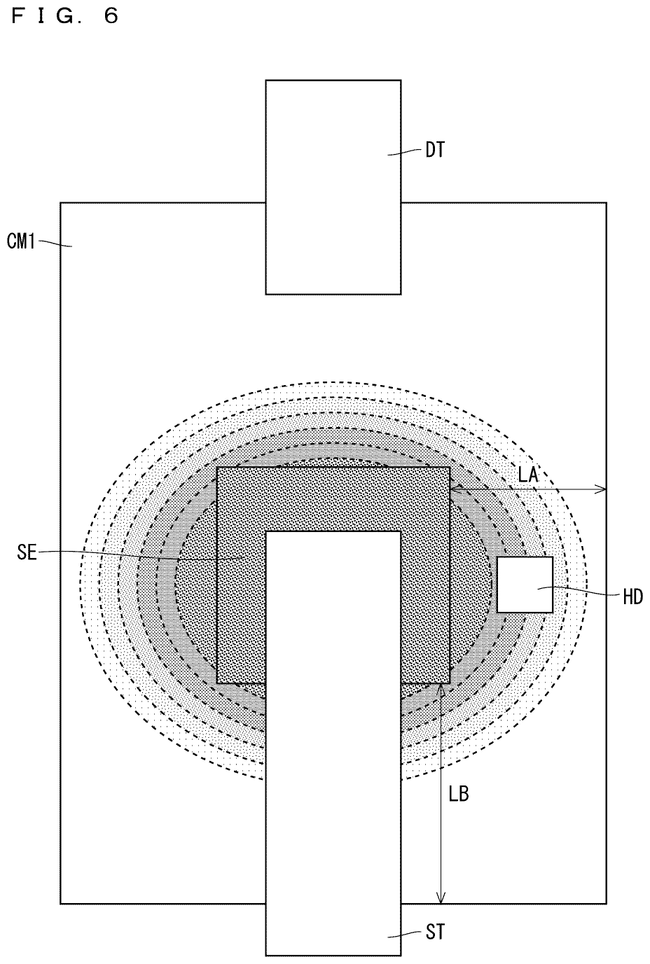

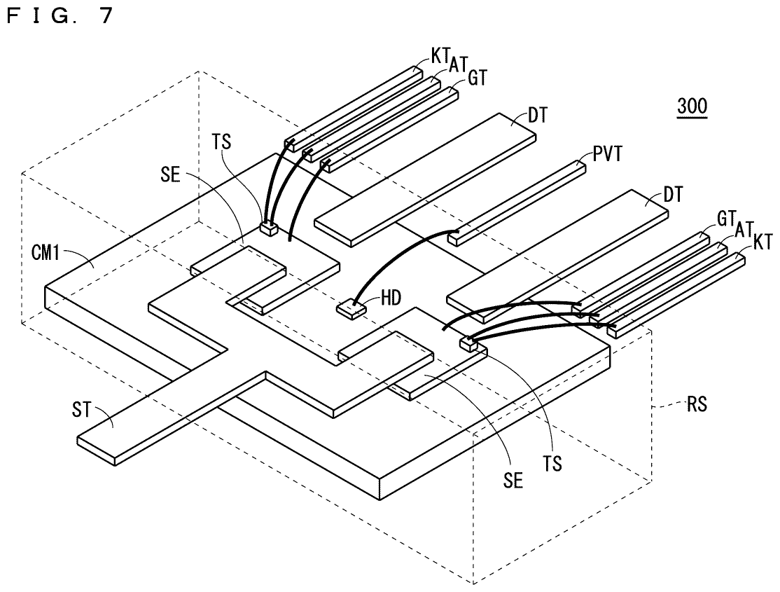

FIG. 6 is a conceptual diagram illustrating a temperature distribution of the conductor plate CM1 when the semiconductor element SE is energized and represents a magnitude of the temperature by a density of dot hatching. As illustrated in FIG. 6, an elliptical temperature distribution is formed in which the temperature decreases outwards with the semiconductor element SE at the center having the maximum temperature. A major diameter of the ellipse is parallel to a short side of the conductor plate CM1, and a region having a high temperature extends to a portion near a portion in which the high breakdown voltage diode HD is mounted.

The high breakdown voltage diode HD is thus disposed in a portion having a shorter distance from the semiconductor element SE to the end surface of the conductor plate CM1, so that thermal bonding between the semiconductor element SE and the high breakdown voltage diode HD is increased to increase the action to counteract a temperature dependency of the MOS transistor Q1 (FIG. 1) as a MOSFET to thereby improve detection accuracy of the overcurrent detection circuit 90.

Since the drain terminal DT and a conductive material to bond the drain terminal DT to the conductor plate CM1 are arranged in a portion having a longer distance to the end surface, arrangements of the drain terminal DT and the conductive material are limited if the high breakdown voltage diode HD is disposed in this portion, but the limitation on the arrangements of the drain terminal DT and the conductive material is eliminated by disposing the high breakdown voltage diode HD in the portion having the shorter distance to the end surface to improve design freedom of the semiconductor device.

An example in which the conductor plate CM1 is rectangular in plan view has been described with reference to FIG. 5, but, if the conductor plate CM1 is square in plan view, the temperature distribution of the conductor plate CM1 is non-uniform when the semiconductor element SE is not disposed at the center, and the distance LA and the distance LB are not equal, so that detection accuracy of the overcurrent detection circuit 90 can be improved in this case by disposing the high breakdown voltage diode HD in a portion having a shorter distance.

### Embodiment 3

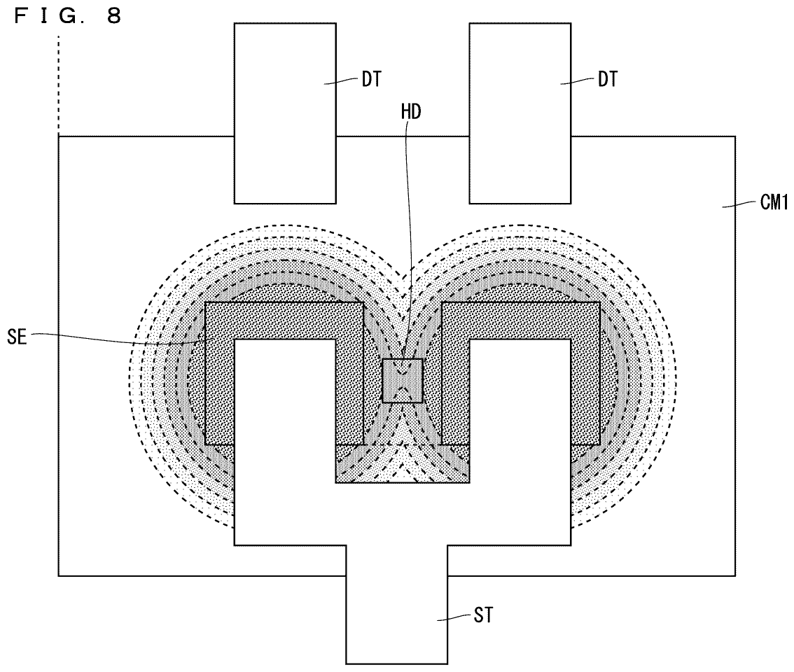

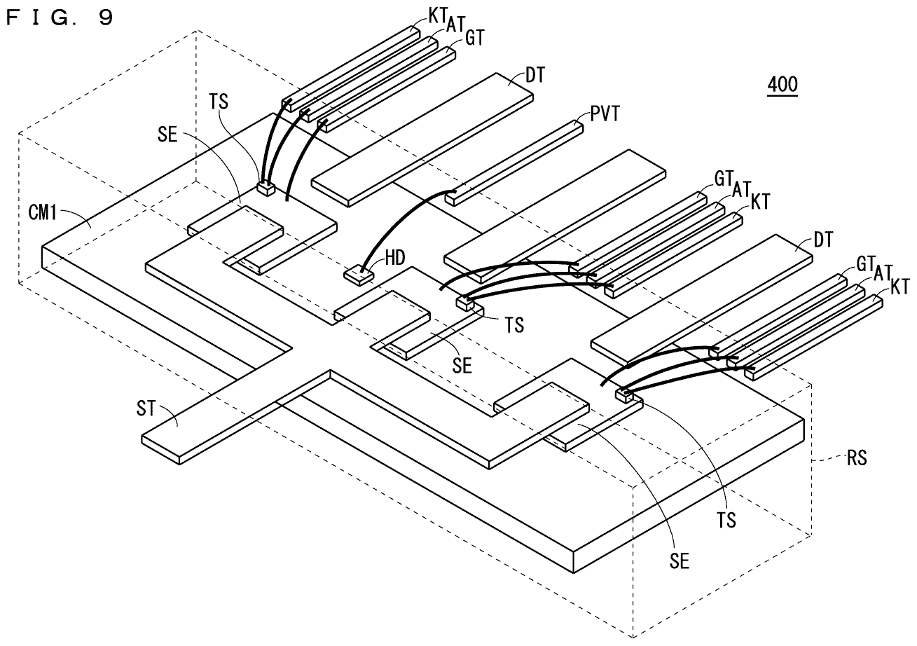

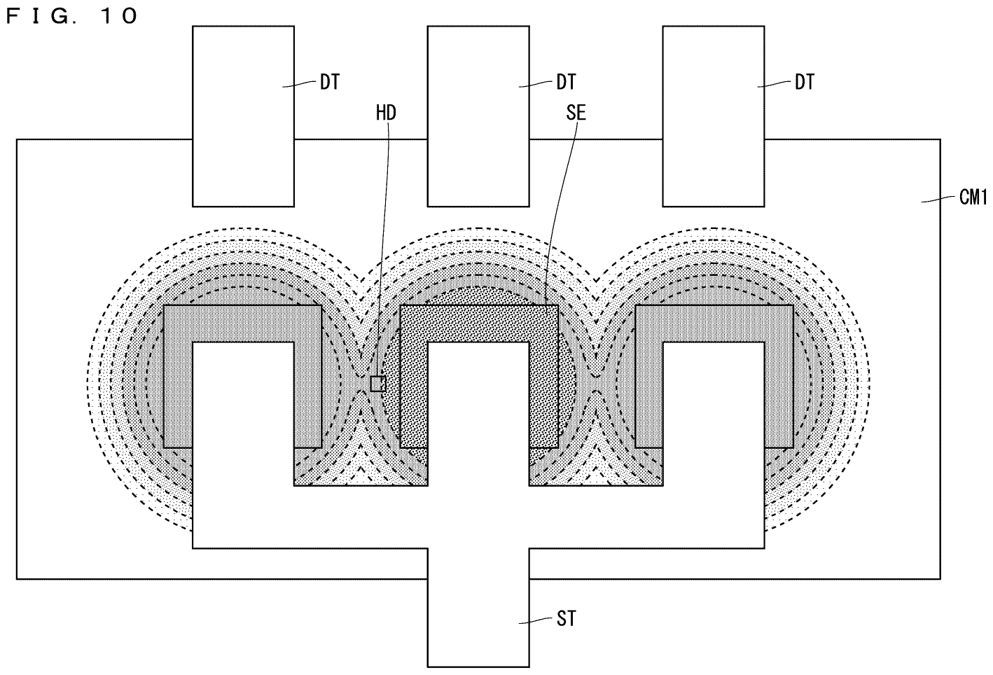

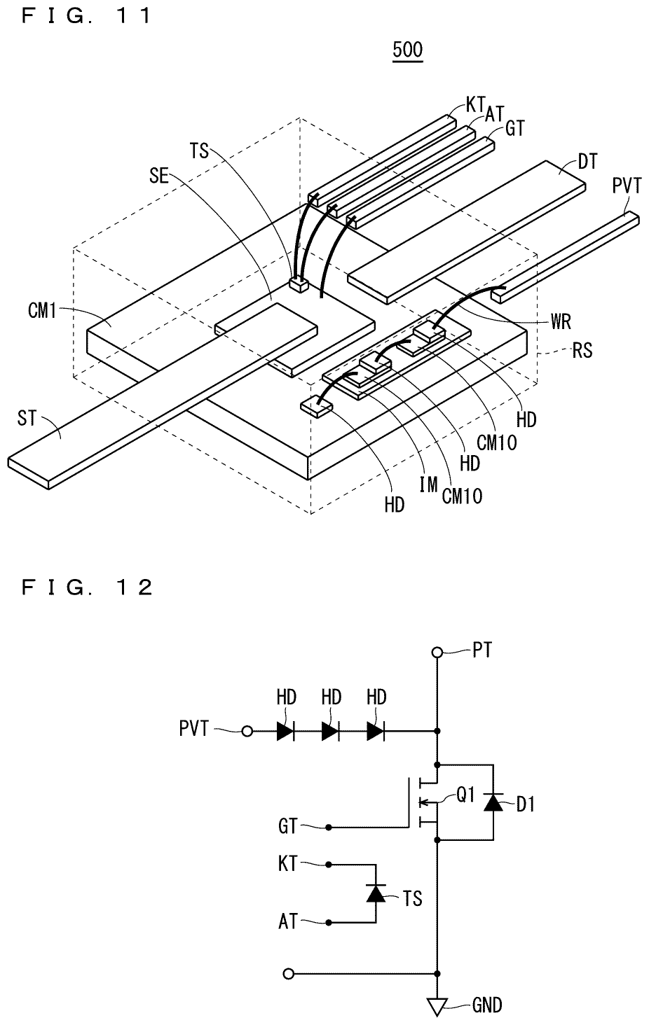

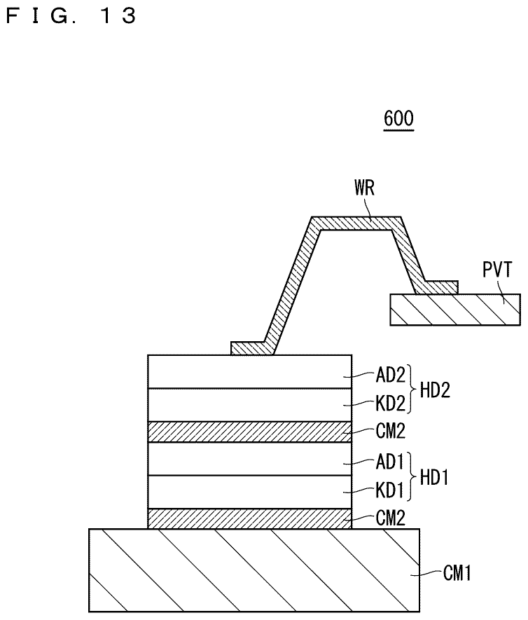

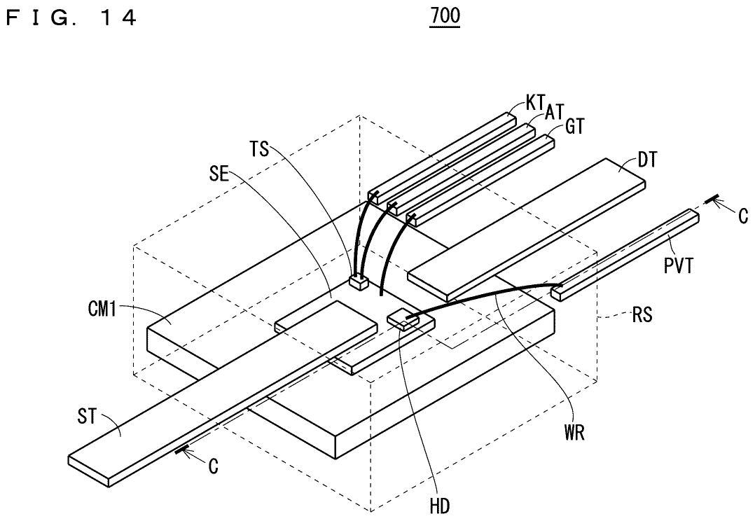

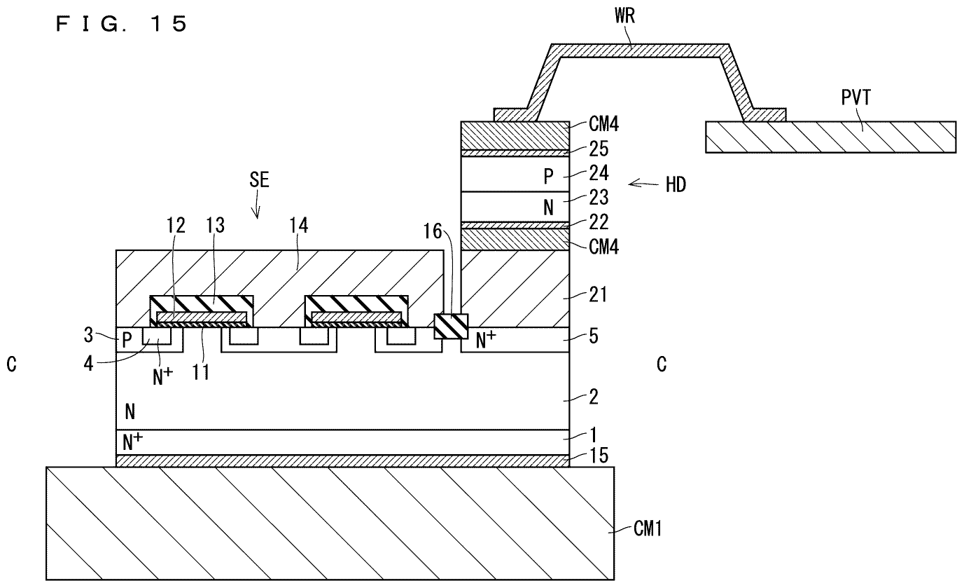

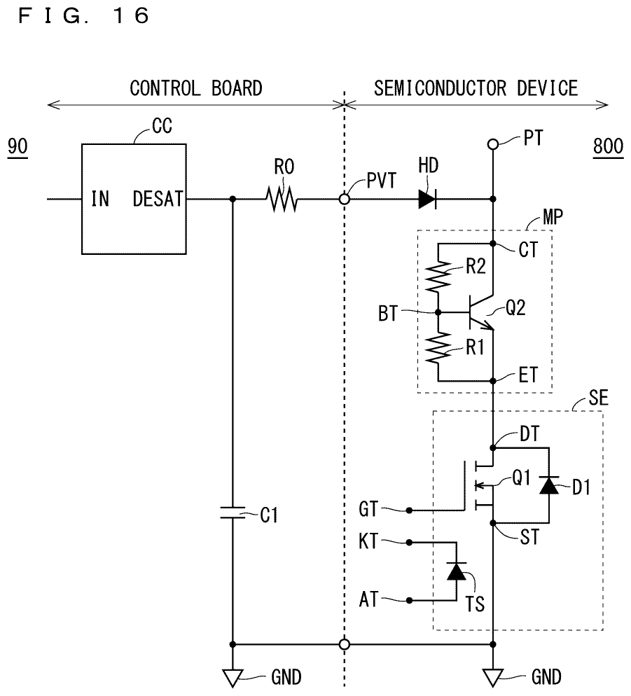

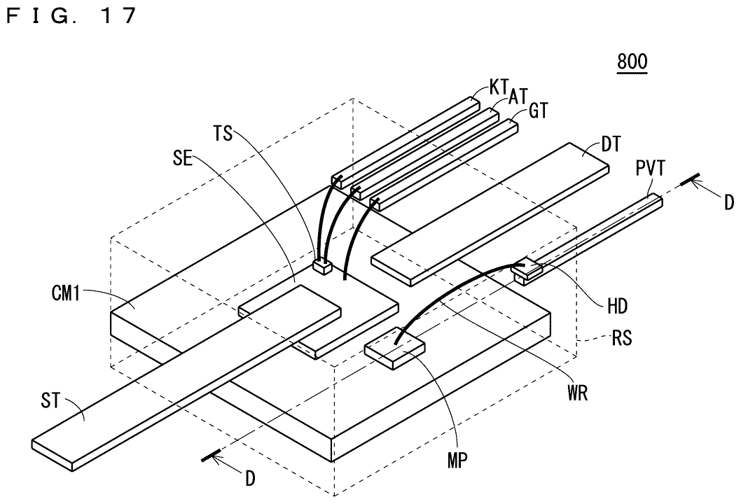

FIG. 7 is a perspective view illustrating a configuration of a semiconductor device 300 according to Embodiment 3. In FIG. 7, the same components as those of the semiconductor device 100 having been described with reference to FIG. 2 bear the same reference signs as those of the same components, and redundant description will be omitted.

The semiconductor device 300 illustrated in FIG. 7 includes two semiconductor elements SE arranged in parallel on the upper surface of the conductor plate CM1. The source terminal ST is connected in parallel to each of the two semiconductor elements SE, the temperature sensor TS is mounted on each of the semiconductor elements SE, and the cathode electrode and the anode electrode, which are not illustrated, provided on the upper surface of the temperature sensor TS are respectively electrically connected to the one end of the cathode terminal KT and the one end of the anode terminal AT as the plate-like conductive materials via the wires WR.

An unillustrated gate pad on the upper surface of each of the semiconductor elements SE is electrically connected to the one end of the gate terminal GT as the plate-like conductive material via the wire WR.

Two drain terminals DT for the two semiconductor elements SE are connected to the upper surface of the conductor plate CM1.

The high breakdown voltage diode HD is mounted between the two semiconductor elements SE arranged on the upper surface of the conductor plate CM1. When the two semiconductor elements SE are energized, the temperature of the conductor plate CM1 increases with the two semiconductor elements SE as a heat source, and, in a region in which the semiconductor elements SE are adjacent to each other, the temperature increases due to thermal interference.

FIG. 8 is a conceptual diagram illustrating a temperature distribution of the conductor plate CM1 when the two semiconductor elements SE are energized and represents a magnitude of the temperature by a density of dot hatching. As illustrated in FIG. 8, in the region in which the semiconductor elements SE are adjacent to each other, the temperature is higher than that in the other concentric region due to thermal interference. The high breakdown voltage diode HD is disposed in such a region in which thermal interference is caused, so that thermal bonding between the semiconductor elements SE and the high breakdown voltage diode HD is increased to increase the action to counteract the temperature dependency of the MOS transistor Q1 (FIG. 1) as the MOSFET to thereby improve detection accuracy of the overcurrent detection circuit 90.

### Embodiment 4

FIG. 9 is a perspective view illustrating a configuration of a semiconductor device 400 according to Embodiment 4. In FIG. 9, the same components as those of the semiconductor device 100 having been described with reference to FIG. 2 bear the same reference signs as those of the same components, and redundant description will be omitted.

The semiconductor device 400 illustrated in FIG. 9 includes three semiconductor elements SE arranged in parallel on the upper surface of the conductor plate CM1. The source terminal ST is connected in parallel to each of the three semiconductor elements SE, the temperature sensor TS is mounted on each of the semiconductor elements SE, and the cathode electrode and the anode electrode, which are not illustrated, provided on the upper surface of the temperature sensor TS are respectively electrically connected to the one end of the cathode terminal KT and the one end of the anode terminal AT as the plate-like conductive materials via the wires WR.

An unillustrated gate pad on the upper surface of each of the semiconductor elements SE is electrically connected to the one end of the gate terminal GT as the plate-like conductive material via the wire WR.

Three drain terminals DT for the three semiconductor elements SE are connected to the upper surface of the conductor plate CM1.

The high breakdown voltage diode HD is mounted in a region between the semiconductor element SE at the center and the semiconductor element SE to the left of the semiconductor element SE at the center at a position closer to the semiconductor element SE at the center. When the three semiconductor elements SE are energized, the temperature of the conductor plate CM1 increases with the three semiconductor elements SE as a heat source, and, in a region in which the semiconductor elements SE are adjacent to one another, the temperature increases due to thermal interference.

FIG. 10 is a conceptual diagram illustrating a temperature distribution of the conductor plate CM1 when the three semiconductor elements SE are energized and represents a magnitude of the temperature by a density of dot hatching. As illustrated in FIG. 10, in the region in which the semiconductor elements SE are adjacent to one another, the temperature is higher than that in the other concentric region due to thermal interference.

Since the semiconductor element SE at the center has the highest temperature due to thermal interference, the high breakdown voltage diode HD is disposed closer to the semiconductor element SE at the center, so that thermal bonding between the semiconductor elements SE and the high breakdown voltage diode HD is increased to increase the action to counteract the temperature dependency of the MOS transistor Q1 (FIG. 1) as the MOSFET to thereby improve detection accuracy of the overcurrent detection circuit 90. While an example in which the three semiconductor elements SE are arranged on the upper surface of the conductor plate CM1 has been described in the present embodiment, the number of semiconductor elements SE is not limited to three, and this configuration is effective when an odd number of semiconductor elements SE, such as five and seven semiconductor elements SE, are arranged.

### Embodiment 5

FIG. 11 is a perspective view illustrating a configuration of a semiconductor device 500 according to Embodiment 5. In FIG. 11, the same components as those of the semiconductor device 100 having been described with reference to FIG. 2 bear the same reference signs as those of the same components, and redundant description will be omitted. FIG. 12 shows an equivalent circuit diagram of the semiconductor device 500.

The configurations of the semiconductor devices 100 to 400 according to Embodiments 1 to 4 in each of which the high breakdown voltage diode HD is mounted on the conductor plate CM1 have been described, but, if a plurality of high breakdown voltage diodes HD are arranged on the conductor plate CM1, they cannot electrically be connected in series.

In the semiconductor device 500 illustrated in FIG. 11, an insulating substrate IM having two conductor patterns CM10 is mounted on the conductor plate CM1, and high breakdown voltage diodes HD are mounted on the respective conductor patterns CM10 so that cathodes thereof oppose the respective conductor patterns CM10. A single high breakdown voltage diode HD is mounted on a portion of the conductor plate CM1 near the insulating substrate IM so that a cathode thereof opposes the conductor plate CM1.

The three diodes are arranged in a line, an anode of one of the high breakdown voltage diodes HD (a first diode) closest to the control terminal PVT is electrically connected to the one end of the control terminal PVT via a wire WR, and one of the conductor patterns CM10 on which the closest high breakdown voltage diode HD is mounted and an anode of the next one of the high breakdown voltage diodes HD are electrically connected via a wire WR. One of the conductor patterns CM10 on which the next high breakdown voltage diode HD is mounted and an anode of one of the high breakdown voltage diodes HD (a second diode) on the conductor plate CM1 are electrically connected via a wire WR.

Such a configuration allows for series connection of the three high breakdown voltage diodes HD as shown in FIG. 12 and increases the action to counteract the temperature dependency of the MOS transistor Q1 (FIG. 1) as the MOSFET to improve detection accuracy of the overcurrent detection circuit 90.

The number of arranged high breakdown voltage diodes HD is not limited to three, and only two or more high breakdown voltage diodes HD can increase the action to counteract the temperature dependency of the MOS transistor Q1.

### Embodiment 6

FIG. 13 is a cross-sectional view illustrating a partial configuration of a semiconductor device 600 according to the present embodiment and is a cross-sectional view corresponding to FIG. 4 in Embodiment 1. As illustrated in FIG. 13, the semiconductor device 600 has a configuration in which high breakdown voltage diodes HD1 and HD2 are stacked on the conductor plate CM1 in this order.

A cathode layer KD1 of the high breakdown voltage diode HD1 is connected to the conductor plate CM1 by a conductive material CM2, an anode layer AD1 of the high breakdown voltage diode HD1 is connected to a cathode layer KD2 of the high breakdown voltage diode HD2 by a conductive material CM2, one end of a wire WR is connected to an anode layer AD2 of the high breakdown voltage diode HD2 by wire bonding, and the other end of the wire WR is connected to the control terminal PVT.

A plurality of high breakdown voltage diodes are stacked as described above, so that the plurality of high breakdown voltage diodes can be connected in series with a simpler configuration to manufacture the semiconductor device having the increased action to counteract the temperature dependency of the MOS transistor Q1 at a lower cost.

### Embodiment 7

FIG. 14 is a perspective view illustrating a configuration of a semiconductor device 700 according to Embodiment 7. FIG. 15 is a cross-sectional view taken along the line C-C of FIG. 14. In FIG. 14, the same components as those of the semiconductor device 100 having been described with reference to FIG. 2 bear the same reference signs as those of the same components, and redundant description will be omitted.

In the semiconductor device 700 illustrated in FIG. 14, the high breakdown voltage diode HD is mounted on the upper surface of the semiconductor element SE. While a surface electrode that functions as the source electrode of the MOS transistor Q1 is provided in the upper surface of the semiconductor element SE, an electrode electrically separated from the surface electrode and having the same potential as the drain electrode of the MOS transistor Q1 is provided in the upper surface of the semiconductor element SE, and the high breakdown voltage diode HD is mounted on the electrode.

By mounting the high breakdown voltage diode HD on the MOS transistor Q1 as the switching element, the high breakdown voltage diode HD is disposed in close proximity to the switching element as a heat source, so that thermal bonding between the semiconductor element SE and the high breakdown voltage diode HD can further be increased to further increase the action to counteract the temperature dependency of the MOS transistor Q1.

A cross-sectional configuration of the high breakdown voltage diode HD will be described with reference to FIG. 15. In description made below, N and P refer to conductivity types of a semiconductor, and description will be made based on the assumption that a first conductivity type is an N type and a second conductivity type is a P type in the present disclosure, but the first conductivity type may be the P type and the second conductivity type may be the N type. Furthermore, an N⁺ type indicates that an impurity concentration is higher than that of the N type. Similarly, a P⁺ type indicates that an impurity concentration is higher than that of the P type.

As illustrated in FIG. 15, the semiconductor element SE of the semiconductor device 700 includes a backside electrode 15 (first main electrode) that functions as a drain electrode in a lower surface side thereof, an N⁺ type semiconductor layer 1 and an N type semiconductor layer 2 are provided on the backside electrode 15 in this order, a plurality of P type semiconductor layers 3 are selectively provided in an upper layer portion of the semiconductor layer 2, and N⁺ type semiconductor layers 4 are selectively provided within surfaces of the P type semiconductor layers 3. The semiconductor layer 1 and the semiconductor layer 2 constitute a semiconductor substrate.

An N⁺ type semiconductor layer 5 is selectively provided in the upper layer portion of the semiconductor layer 2 separately from the semiconductor layers 4, and an element separation insulating film 16 is provided between the semiconductor layers 3 and the semiconductor layer 5.

A gate electrode 12 is provided, via a gate insulating film 11, above a portion between end edges of two opposing semiconductor layers 4 provided in adjacent semiconductor layers 3.

An interlayer insulating film 13 is provided to cover the gate insulating film 11 and the gate electrode 12, and a surface electrode 14 (second main electrode) that functions as the source electrode is provided to cover the interlayer insulting film 13. The surface electrode 14 is a film of Al or an aluminum alloy, such as AlSi.

While the configuration of the MOS transistor Q1 as the MOSFET has been described above, the MOS transistor Q1 has a known transistor structure formed by known technology, so that description on a manufacturing process and the like is omitted.

A surface electrode 21 that has the same thickness as and is made of the same material as the surface electrode 14 is provided on a top of the semiconductor layer 5, and a cathode electrode 22 of the high breakdown voltage diode HD is connected to the surface electrode 21 via a conductive material CM4. An N type cathode layer 23 and a P type anode layer 24 are stacked on the cathode electrode 22 in this order, an anode electrode 25 is provided on the anode layer 24, the conductive material CM4 is provided on the anode electrode 25, one end of a wire WR is connected to the conductive material CM4 by wire bonding, and the other end of the wire WR is connected to the control terminal PVT. The same material as the conductive material CM2 described above can be used as the conductive material CM4.

The backside electrode 15 that functions as the drain electrode is a film of aluminum (Al) or an aluminum alloy, such as AlSi, formed on the N⁺ type semiconductor layer 1, and, when the N⁺ type semiconductor layer 5 is provided in the upper layer portion of the N type semiconductor layer 2, an N⁺/N/N⁺ stack structure is formed from the backside electrode 15, and the N⁺ type semiconductor layer 1 and the N⁺ type semiconductor layer 5 have substantially the same potential. The cathode electrode 22 of the high breakdown voltage diode HD is thus pseudo-connected to the drain electrode, so that a configuration in which the high breakdown voltage diode HD is mounted on the MOS transistor Q1 can be achieved.

### Embodiment 8

FIG. 16 is a circuit diagram showing configurations of a semiconductor device 800 according to Embodiment 8 according to the present disclosure and the overcurrent detection circuit 90. In FIG. 16, the same components as those of the semiconductor device 100 having been described with reference to FIG. 1 bear the same reference signs as those of the same components, and redundant description will be omitted.

The semiconductor device 800 shown in FIG. 16 includes a multiplier circuit MP provided between the cathode of the high breakdown voltage diode HD and the drain terminal DT of the MOS transistor Q1.

The multiplier circuit MP is a VBE type multiplier circuit that includes an NPN type transistor Q2 having a collector terminal CT connected to the cathode of the high breakdown voltage diode HD and an emitter terminal ET connected to the drain terminal DT of the MOS transistor Q1, a resistor R1 (first resistor) connected between a base terminal BT and the emitter terminal ET of the transistor Q2, and a resistor R2 (second resistor) connected between the base terminal BT and the collector terminal CT of the transistor Q2.

The multiplier circuit MP can amplify a forward voltage of a PN junction diode including a base and an emitter of the transistor Q2 using the resistors R1 and R2 and adjust the forward voltage to a voltage level determined by resistance values of the resistors R1 and R2.

That is to say, a collector-emitter voltage V_{CE} of the transistor Q2 is represented by an equation V_{CE}=(1+R₂/R₁)·V_{BE}, where R₁ is a resistance value of the resistor R1, R₂ is a resistance value of the resistor R2, and V_{BE} is a base-emitter voltage of the transistor Q2. The collector-emitter voltage V_{CE} of the transistor Q2 can thus be adjusted to any value by adjusting the resistance values of the resistors R1 and R2.

The base-emitter voltage V_{BE} has negative temperature characteristics as with the forward voltage of the diode and can be amplified by resistance ratios of the resistance values R₁ and R₂ without forming a series circuit of the diode.

FIG. 17 is a perspective view illustrating a configuration of the semiconductor device 800 according to Embodiment 8. In FIG. 17, the same components as those of the semiconductor device 100 having been described with reference to FIG. 2 bear the same reference signs as those of the same components, and redundant description will be omitted.

In the semiconductor device 800 illustrated in FIG. 17, the multiplier circuit MP is mounted on the upper surface of the conductor plate CM1 at a position away from the semiconductor element SE, and the high breakdown voltage diode HD is mounted on one end of the control terminal PVT. The multiplier circuit MP and the high breakdown voltage diode HD are electrically connected via a wire WR. An upper surface and a lower surface of the multiplier circuit MP respectively serve as a collector and an emitter.

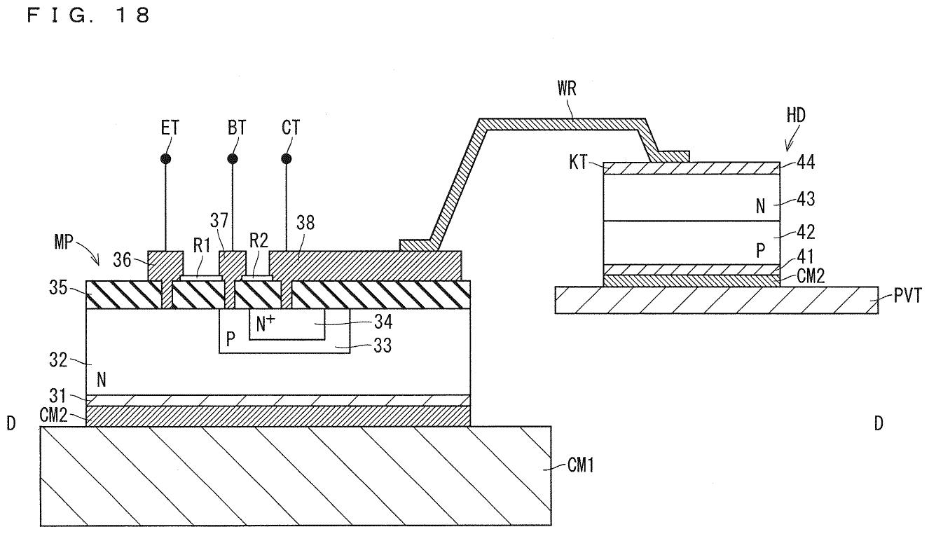

FIG. 18 is a cross-sectional view taken along the line D-D of FIG. 17. As illustrated in FIG. 18, the multiplier circuit MP includes a backside electrode 31 that functions as an emitter electrode in a lower surface side thereof, and the backside electrode 31 is connected to the conductor plate CM1 via a conductive material CM2.

An N type semiconductor layer 32 is provided on the backside electrode 31, a P type semiconductor layer 33 is selectively provided in an upper layer portion of the semiconductor layer 32, and an N⁺ type semiconductor layer 34 is selectively provided within a surface of the P type semiconductor layer 33.

An interlayer insulating film 35 is provided on the semiconductor layer 32, and an emitter electrode 36 that extends through the interlayer insulating film 35 to the semiconductor layer 32, a base electrode 37 that extends through the interlayer insulating film 35 to the semiconductor layer 33, and a collector electrode 38 that extends through the interlayer insulating film 35 to the semiconductor layer 34 are provided on the interlayer insulating film 35.

The resistor R1 is provided on a portion of the interlayer insulating film 35 between the emitter electrode 36 and the base electrode 37, and the resistor R2 is provided on a portion of the interlayer insulating film 35 between the collector electrode 38 and the base electrode 37. The resistors R1 and R2 are formed of polysilicon layers containing semiconductor impurities, for example, and the resistance values can be adjusted by adjusting the amount of impurities. The resistance values can also be adjusted by adjusting thicknesses of the resistors R1 and R2 using laser trimming technology and the like.

One end of a wire WR is connected to the collector electrode 38 by wire bonding, and the other end of the wire WR is connected to a surface electrode 44 of the high breakdown voltage diode HD mounted on the control terminal PVT. In the high breakdown voltage diode HD, a backside electrode 41 that functions as an anode electrode is connected to the control terminal PVT via a conductive material CM2, a P type anode layer 42 and an N type cathode layer 43 are stacked on the backside electrode 41 in this order, and the surface electrode 44 that functions as a cathode electrode is provided on the cathode layer 43.

The multiplier circuit MP having negative temperature characteristics is disposed near the switching element, which is the heat source, to increase the action to counteract the temperature dependency of the MOS transistor Q1 (FIG. 16) as the MOSFET with a simpler configuration to thereby improve detection accuracy of the overcurrent detection circuit 90.

### Embodiment 9

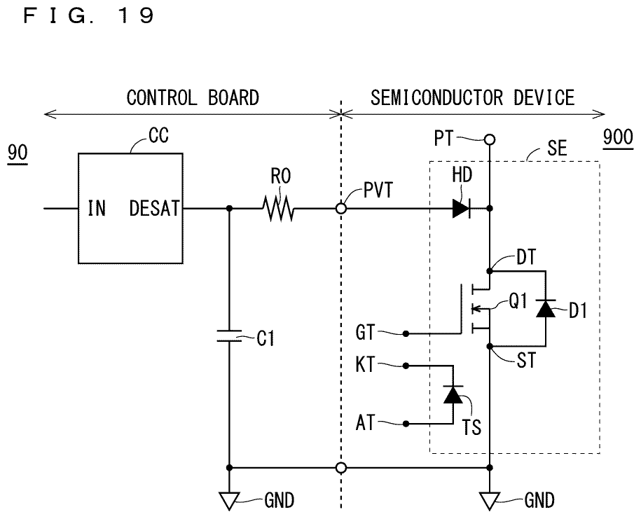

FIG. 19 is a circuit diagram showing configurations of a semiconductor device 900 according to Embodiment 9 according to the present disclosure and the overcurrent detection circuit 90. The semiconductor device 900 shown in FIG. 19 has a configuration in which the high breakdown voltage diode HD is incorporated in the semiconductor element SE. In FIG. 19, the same components as those of the semiconductor device 100 having been described with reference to FIG. 1 bear the same reference signs as those of the same components, and redundant description will be omitted.

FIG. 20 is a perspective view illustrating the configuration of the semiconductor device 900 according to Embodiment 9. In FIG. 207, the same components as those of the semiconductor device 100 having been described with reference to FIG. 2 bear the same reference signs as those of the same components, and redundant description will be omitted.

In the semiconductor device 900 illustrated in FIG. 20, the high breakdown voltage diode HD is provided near a region of the semiconductor element SE in which the source terminal ST is connected on a side opposite a position at which the temperature sensor TS is disposed and is electrically connected to one end of the control terminal PVT via a wire WR. In FIG. 20, the semiconductor element SE and the high breakdown voltage diode HD are divided for the sake of simplicity.

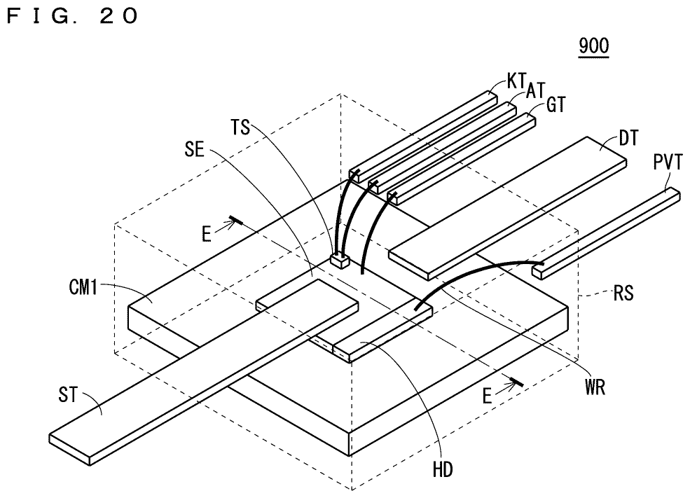

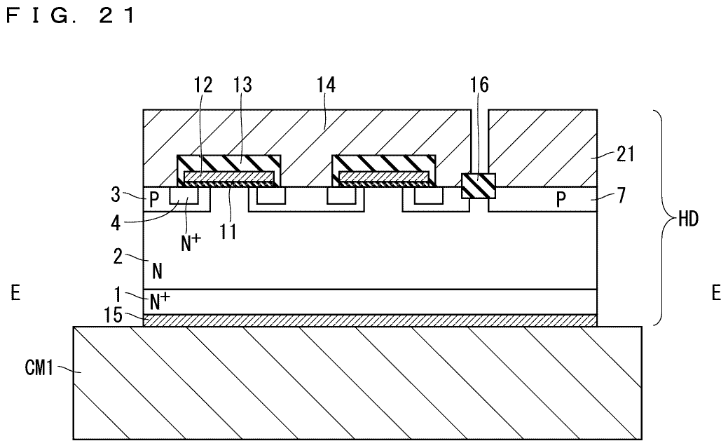

FIG. 21 is a cross-sectional view taken along the line E-E of FIG. 20. As illustrated in FIG. 21, the semiconductor element SE includes the backside electrode 15 that functions as the drain electrode in the lower surface side thereof, the N⁺ type semiconductor layer 1 and the N type semiconductor layer 2 are provided on the backside electrode 15 in this order, the plurality of P type semiconductor layers 3 are selectively provided in the upper layer portion of the semiconductor layer 2, and the N⁺ type semiconductor layers 4 are selectively provided within the surfaces of the P type semiconductor layers 3. The semiconductor layer 1 and the semiconductor layer 2 constitute the semiconductor substrate.

A P type semiconductor layer 7 is selectively provided in the upper layer portion of the semiconductor layer 2, and the element separation insulating film 16 is provided between the semiconductor layers 3 and the semiconductor layer 7.

The gate electrode 12 is provided, via the gate insulating film 11, above the portion between the end edges of two opposing semiconductor layers 4 provided in adjacent semiconductor layers 3.

The interlayer insulating film 13 is provided to cover the gate insulating film 11 and the gate electrode 12, and the surface electrode 14 that functions as the source electrode is provided to cover the interlayer insulting film 13. The surface electrode 14 is the film of Al or an aluminum alloy, such as AlSi.

While the configuration of the MOS transistor Q1 as the MOSFET has been described above, the MOS transistor Q1 has a known transistor structure formed by known technology, so that description on a manufacturing process and the like is omitted.

The surface electrode 21 that has the same thickness as and is made of the same material as the surface electrode 14 is provided on a top of the semiconductor layer 7. The wire WR (FIG. 20) is connected to the surface electrode 21 by wire bonding. The surface electrode 21 functions as the anode electrode, and the surface electrode 21, the semiconductor layer 7, the semiconductor layer 2, the semiconductor layer 1, and the backside electrode 15 constitute the high breakdown voltage diode HD.

By forming the MOS transistor Q1 and the high breakdown voltage diode HD in a common semiconductor substrate as illustrated in FIG. 21, the high breakdown voltage diode HD is disposed at a position in close proximity to the switching element as the heat source, so that thermal bonding can extremely be increased.

### Embodiment 10

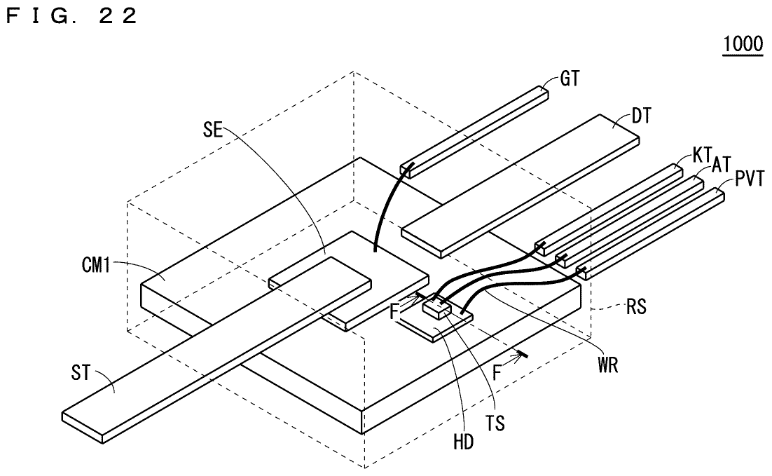

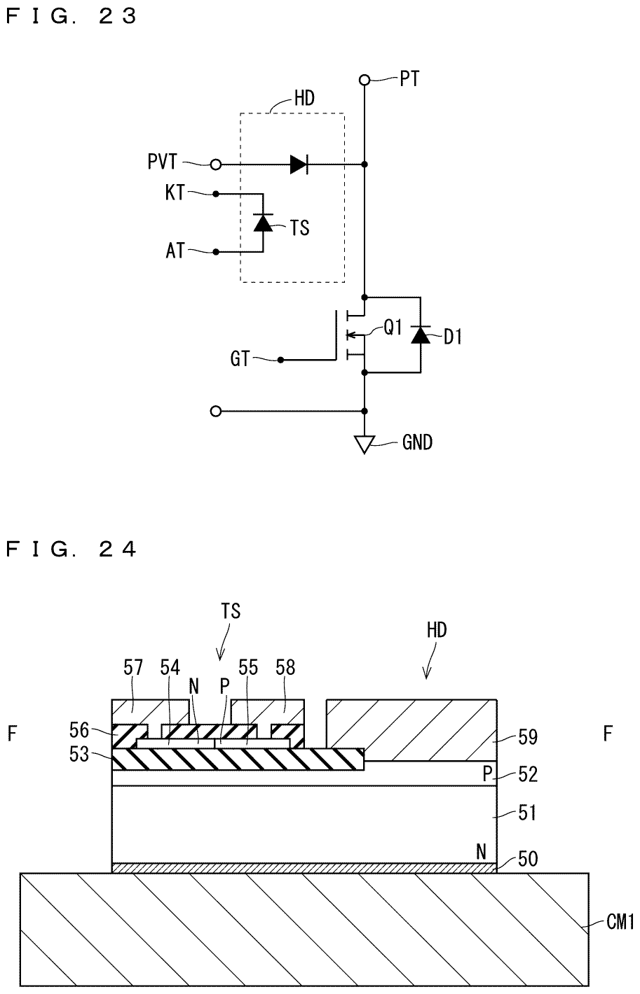

FIG. 22 is a perspective view illustrating a configuration of a semiconductor device 1000 according to Embodiment 10. In FIG. 22, the same components as those of the semiconductor device 100 having been described with reference to FIG. 2 bear the same reference signs as those of the same components, and redundant description will be omitted. FIG. 23 shows an equivalent circuit diagram of the semiconductor device 1000.

While configurations of the semiconductor devices 100 to 900 according to Embodiments 1 to 9 in each of which the temperature sensor TS is mounted on the semiconductor element SE have been shown, the temperature sensor TS is mounted on the high breakdown voltage diode HD in the semiconductor device 1000 illustrated in FIG. 22.

The cathode electrode and the anode electrode, which are not illustrated, provided on the upper surface of the temperature sensor TS are respectively electrically connected to the one end of the cathode terminal KT and the one end of the anode terminal AT via the wires WR. The high breakdown voltage diode HD is electrically connected to the one end of the control terminal PVT via the wire WR.

FIG. 24 is a cross-sectional view taken along the line F-F of FIG. 22. As illustrated in FIG. 24, the high breakdown voltage diode HD includes a backside electrode 50 that functions as a cathode electrode in a lower surface side thereof, an N type semiconductor layer 51 and a P type semiconductor layer 52 are provided on the backside electrode 50 in this order, a silicon oxide film 53 is selectively provided in an upper layer portion of the semiconductor layer 52, and an N type semiconductor layer 54 and a P type semiconductor layer 55 are diode-connected to the silicon oxide film 53 to form the temperature sensor TS. The semiconductor layer 54 and the semiconductor layer 55 are formed by doping a polysilicon layer with N type impurities and P type impurities, respectively.

The semiconductor layer 54 and the semiconductor layer 55 are covered with an interlayer insulating film 56 of boro-phospho silicate glass (BPSG), tetra ethyl orthosilicate (TEOS), low temperature oxide (LTO), and the like. A cathode electrode 57 and an anode electrode 58 of the temperature sensor TS that extend through the interlayer insulating film 56 respectively to the semiconductor layer 54 and the semiconductor layer 55 are provided on the interlayer insulating film 56. The respective wires WR (FIG. 22) are connected to the cathode electrode 57 and the anode electrode 58 by wire bonding. The temperature sensor TS on the semiconductor element SE of each of the semiconductor devices 100 to 900 according to Embodiments 1 to 9 has a similar configuration to the sensor TS in FIG. 24.

A surface electrode 59 that functions as an anode electrode of the high breakdown voltage diode HD is provided on the semiconductor layer 52 in a region in which the silicon oxide film 53 is not provided, and the wire WR (FIG. 22) is connected to the surface electrode 59 by wire bonding.

By having such a configuration, the temperature sensor TS is incorporated into the high breakdown voltage diode HD, and the semiconductor element SE has a configuration in which only the MOS transistor Q1 and the diode D1 are included as illustrated in FIG. 23.

When the MOS transistor Q1 is formed of a wide bandgap semiconductor, such as silicon carbide (SiC) and gallium nitride (GaN), a chip size, that is, a size of an SiC substrate or a GaN substrate can be reduced by disposing the temperature sensor TS on the high breakdown voltage diode HD formed of a silicon semiconductor, so that a cost of the semiconductor device can be reduced. Forming a silicon semiconductor element and a wide bandgap semiconductor element as separate chips can simplify a manufacturing process to reduce a cost of the semiconductor device.

While the present disclosure has been described in detail, the foregoing description is in all aspects illustrative and not restrictive. It is understood that numerous unillustrated modifications can be devised without departing from the scope of the present disclosure.

Embodiments can freely be combined with each other and can be modified or omitted as appropriate within the scope of the present disclosure.

1. A semiconductor device comprising:
a first main terminal that is provided with a first potential;
a second main terminal that is provided with a second potential lower than the first potential;
a control terminal that is connected to an overcurrent detection circuit provided externally;
at least one semiconductor element that includes a MOS transistor connected between the first main terminal and the second main terminal; and
at least one diode that has a cathode electrically connected to the first main terminal and an anode electrically connected to the control terminal and protects the overcurrent detection circuit, wherein
the at least one semiconductor element is mounted on a conductor plate, and
the at least one semiconductor element and the at least one diode are sealed with an insulating resin.

2. The semiconductor device according to claim 1, wherein
the at least one diode is mounted on the conductor plate.

3. The semiconductor device according to claim 2, wherein
the at least one semiconductor element is mounted at a position on the conductor plate at which a first distance from the at least one semiconductor element to a first end surface of the conductor plate and a second distance from the at least one semiconductor element to a second end surface orthogonal to the first end surface are different,
the first distance is shorter than the second distance, and
the at least one diode is mounted on a side of the first end surface on the conductor plate.

4. The semiconductor device according to claim 1, wherein
the at least one semiconductor element comprises two semiconductor elements,
the two semiconductor elements are mounted on the conductor plate in a line to be spaced apart from each other, and
the at least one diode is mounted between the two semiconductor elements.

5. The semiconductor device according to claim 1, wherein
the at least one semiconductor element comprises an odd number of semiconductor elements, the odd number being three or more,
the three or more semiconductor elements are mounted on the conductor plate in a line to be spaced apart from one another, and
the at least one diode is mounted between a semiconductor element at the center and another semiconductor element external to the semiconductor element at the center to be closer to the semiconductor element at the center.

6. The semiconductor device according to claim 1, wherein
the at least one diode comprises a plurality of diodes,
the plurality of diodes are mounted on respective conductor patterns of an insulating substrate arranged over the conductor plate in a line to be spaced apart from one another and are electrically connected in series, and
from among the plurality of diodes, an anode of a first diode at one end of the arrangement is electrically connected to the control terminal, and a cathode of a second diode at the other end of the arrangement is electrically connected to the first main terminal.

7. The semiconductor device according to claim 1, wherein
the at least one diode comprises a plurality of diodes, and
the plurality of diodes are mounted on the conductor plate to be stacked so that cathodes thereof are on a side of the conductor plate, the plurality of diodes being electrically connected in series.

8. The semiconductor device according to claim 1, wherein
the at least one semiconductor element includes:
a first main electrode that opposes the conductor plate and a second main electrode that is on an opposite side from the first main electrode; and
a surface electrode that is adjacent to the second main electrode and is electrically separated from the second main electrode,
the surface electrode is electrically connected to the first main electrode via an interior of the at least one semiconductor element, and
the at least one diode is mounted on the surface electrode of the at least one semiconductor element so that the cathode is electrically connected to the surface electrode.

9. The semiconductor device according to claim 1 further comprising
a multiplier circuit that is interposed between the cathode of the at least one diode and the first main terminal, wherein
the multiplier circuit includes:
a transistor that has a collector electrically connected to the cathode of the at least one diode and an emitter electrically connected to the first main terminal;
a first resistor that is electrically connected between a base of the transistor and the emitter; and
a second resistor that is electrically connected between the base and the collector.

10. The semiconductor device according to claim 1, wherein
the at least one semiconductor element includes:
a first main electrode that opposes the conductor plate and a second main electrode that is on an opposite side from the first main electrode; and
a surface electrode that is adjacent to the second main electrode and is electrically separated from the second main electrode, and
the at least one diode is provided within the at least one semiconductor element so that the anode is connected to the surface electrode and the cathode is connected to the first main electrode.

11. The semiconductor device according to claim 1 further comprising
a temperature sensor that is mounted on the at least one semiconductor element and detects a temperature of the at least one semiconductor element, wherein
the temperature detected by the temperature sensor is fed back to the overcurrent detection circuit.

12. The semiconductor device according to claim 1 further comprising
a temperature sensor that is mounted on the at least one diode and detects a temperature of the at least one semiconductor element, wherein
the temperature detected by the temperature sensor is fed back to the overcurrent detection circuit.

13. The semiconductor device according to claim 1, wherein
the overcurrent detection circuit detects a desaturation voltage of the MOS transistor to provide overcurrent protection to the MOS transistor.
